(19) United States
(12) Patent Application Publication
(10) Pub. No.: US 2025/0087253 A1
(43) Pub. Date: Mar. 13, 2025

(54) MULTI-CIRCUIT CONTROL SYSTEM AND READING METHOD FOR STATUS INFORMATION THEREOF

(71) Applicant: MACRONIX International Co., Ltd., Hsinchu (TW)

(72) Inventors: Shuo-Nan Hung, Hsinchu County (TW); Shih-Chou Juan, Taoyuan City (TW); Chun-Lien Su, Taichung City (TW)

(73) Assignee: MACRONIX International Co., Ltd., Hsinchu (TW)

(21) Appl. No.: 18/464,262

(22) Filed: Sep. 11, 2023

(51) Int. Cl. G11C 7/10

(52) U.S. Cl. CPC G11C 7/1036; G11C 7/1012; G11C 7/1063

(57) ABSTRACT

Disclosed are a multi-circuit control system and a reading method for status information thereof. The multi-circuit control system includes a first circuit and N second circuits. The second circuit is, for example a three dimensional NAND flash memory circuit, and the multi-circuit control system provides a storage media with high-performance and high-capacity. The first circuit provides a read clock signal. The second circuits are coupled in series, and coupled to the first circuit. Each of the second circuits has at least one first data shifter. The at least one data shifter is used to load status information of each of the second circuits, and shift out each of the status information to a second circuit of a previous stage or the first circuit or the first chip obtains the status information of each of the second circuits through a parallel transmission scheme.

### BACKGROUND

### Field of the Disclosure

The present disclosure relates to a multi-circuit control system and a method for reading status information thereof, and in particular relates to a multi-circuit control system of a memory circuit and a method for reading status information thereof.

### Description of Related Art

In a multi-circuit system (such as a memory system), a main circuit often needs to monitor the working status of multiple slave circuits, and thereby knowing whether each slave circuit is in a busy state. In the conventional technology, when the master circuit needs to read the status information of each slave circuit to know whether each slave circuit is in a busy state, it is necessary for the master circuit to send status information read commands one by one, and then receive the status information of the slave circuits one by one. When there are too many slave circuits, it takes a lot of time to send the read command of status information to all the slave circuits, which causes a waste of time and reduces the working performance of the system.

### SUMMARY OF THE DISCLOSURE

The present disclosure provides a multi-circuit control system and a method for reading status information thereof, which may improve the efficiency of reading status information of a second circuit.

A multi-circuit control system of the disclosure includes a first circuit and N second circuits. The first circuit provides a read clock signal. The second circuits are sequentially coupled in series and coupled to the first circuit. Each of the second circuits has at least one first data shifter. The at least one first data shifter is used to load status information of each of the second circuits, and shift out each of the status information to a second circuit of a previous stage or the first circuit according to the read clock signal, or the first chip obtains the status information of each of the second circuits through a parallel transmission scheme.

The method for reading status information of the present disclosure includes: making the first circuit provide a read clock signal; making N second circuits sequentially coupled to each other in series, and coupling the second circuit to the first circuit; providing at least one first data shifter in each of the second circuits, so that the at least one first data shifter loads status information of each of the second circuits; and, making each of the second circuits shift out each of the status information to each of the second circuits of a previous stage or the first circuit according to the read clock signal, or making the first chip obtain the status information of each of the second circuits through a parallel transmission scheme.

Based on the above, in the multi-circuit control system of the present disclosure, the first circuit may read the clock signal so that the status information of multiple second circuits may be sequentially read out with the clock cycle of the clock signal. In this way, the first circuit may save time wasted by issuing a read command for each of the second circuits, and thereby improving the working performance of the multi-circuit control system.

### BRIEF DESCRIPTION OF THE DRAWINGS

FIG. 1 is a schematic diagram of a multi-circuit control system according to an embodiment of the present disclosure.

FIG. 2 is a schematic diagram of a multi-circuit control system according to another embodiment of the present disclosure.

FIG. 3 is a schematic diagram illustrating the implementation of each of the second circuits in a multi-circuit control system of an embodiment of the present disclosure.

FIG. 4 is a flowchart of a method for reading status information of a multi-circuit control system according to an embodiment of the present disclosure.

FIG. 5 shows an action waveform diagram of a multi-circuit control system of an embodiment of the present disclosure.

FIG. 6A shows an action waveform diagram of another implementation of a multi-circuit control system of an embodiment of the present disclosure.

FIG. 6B is a schematic diagram of a multi-circuit control system according to another embodiment of the present disclosure.

FIG. 7 is a schematic diagram of a multi-circuit control system according to another embodiment of the present disclosure.

FIG. 8 is a flowchart of a method for reading status information of a multi-circuit control system according to an embodiment of the present disclosure.

### DESCRIPTION OF EMBODIMENTS

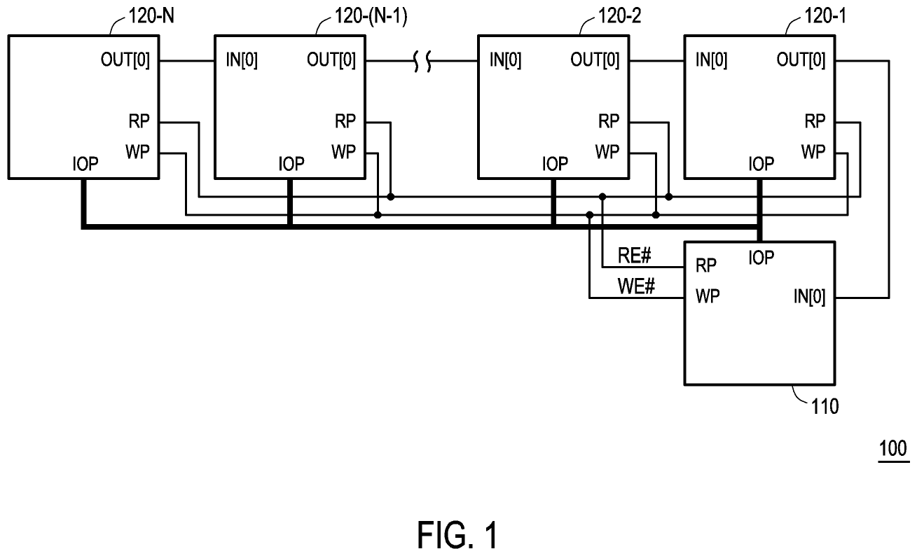

Please refer to FIG. 1, FIG. 1 is a schematic diagram of a multi-circuit control system according to an embodiment of the present disclosure. The multi-circuit control system 100 includes a first circuit 110 and a plurality of second circuits 120-1 to 120-N. The second circuits 120-1 to 120-N are coupled in series with each other, and the second circuits 120-1 to 120-N are also coupled with the first circuit 110. The second circuit 120-1 of the first stage is coupled between the second circuit 120-2 of the second stage and the first circuit 110. The second circuits 120-2 to 120-N of the second stage to the N-th stage are sequentially coupled behind the second circuit 120-1 of the first stage. Each of the second circuits 120-1 to 120-N has a data output port OUT[0] and a data input port IN[0], and the first circuit 110 has a data input port IN[0]. In detail, the data output port OUT[0] of the second circuit 120-1 of the first stage is coupled to the data input port IN[0] of the first circuit 110. The data input ports IN[0] of the second circuits 120-1 to 120-(N-1) from the first stage to the N-1-th stage are respectively coupled to the data output ports OUT[0] of the second circuits 120-2 to 120-N of the subsequent stage (second stage to N-th stage).

In addition, each of the first circuit 110 and the second circuits 120-1 to 120-N has a write signal transmission port WP and a read signal transmission port RP. The write signal transmission ports WP of the first circuit 110 and the second circuits 120-1 to 120-N are coupled to each other and used for transmitting the write signal WE #. The read signal transmission ports RP of the first circuit 110 and the second circuits 120-1 to 120-N are coupled to each other, and the first circuit 110 may transmit the read clock signal RE #to the second circuits 120-1 to 120-N through the read signal transmission port RP. On the other hand, each of the first circuit 110 and the second circuits 120-1 to 120-N may further have a parallel input and output port IOP. The parallel data transmission operation may be performed between the first circuit 110 and each of the second circuits 120-1 to 120-N through the parallel input and output port IOP.

In this embodiment, each of the second circuits 120-1 to 120-N may have a data shifter. The data shifter may be coupled between the data input port IN[0] and the data output port OUT[0] of the corresponding second circuits 120-1 to 120-N. Each of the second circuits 120-1 to 120-N may load the status information thereof into the data shifter, and the data shifter may shift out the stored status information according to the clock cycle of the read clock signal RE #received by the corresponding second circuits 120-1 to 120-N.

In detail, when the first circuit 110 needs to read the status information of the second circuits 120-1 to 120-N, the first circuit 110 may send related commands to the second circuits 120-1 to 120-N through the parallel input and output port IOP. Correspondingly, the second circuits 120-1 to 120-N may load status information thereof into a plurality of data shifters therein. Then, the first circuit 110 may transmit the read clock signal RE #to the second circuits 120-1 to 120-N, and make the multiple data shifters in the second circuits 120-1 to 120-N to shift out the stored status information to the data output port OUT[0] thereof according to the clock cycle of the read clock signal RE #.

According to the coupling form of the multi-circuit control system 100, along with the clock cycle of the read clock signal RE #, the status information of the second circuit 120-1 may be shifted to the first circuit 110 first, and then the status information of the second circuits 120-2 to 120-N of the subsequent stage may be shifted to the second circuits 120-1 to 120-(N-1) of the previous stage. In this way, as the clock cycle of the read clock signal RE #increases, the status information of the second circuits 120-2 to 120-N may be sequentially shifted to the first circuit 110. In this manner, the first circuit 110 may successfully read the status information of all the second circuits 120-1 to 120-N.

Incidentally, the multi-circuit control system 100 of this embodiment may be a memory system, and may be applied in, for example, a solid-state disk (SSD). The first circuit 110 may be a memory controller, and may be set as a master circuit. The second circuits 120-1 to 120-N may be memory circuits, and may be configured as slave circuits. The second circuits 120-1 to 120-N may be NAND, AND or NOR flash memory circuits, for example. Moreover, the first circuit 110 may be disposed on a first chip, and the second circuits 120-1 to 120-N may be respectively disposed on a plurality of different chips.

On the other hand, in an embodiment of the present disclosure, when the first circuit 110 only needs to read the status information of one of the second circuits 120-1 to 120-N, the relevant commands may be sent to the second circuits 120-1 to 120-N through the parallel input and output port IOP. The selected second circuit (one of the second circuits 120-1 to 120-N) may be notified through the transmitted data packet, so as to send the status information thereof to the first circuit 110 through the parallel input and output port IOP. In addition, when the first circuit 110 reads the status information of the selected second circuit through the parallel input and output port IOP thereof, the shifting operation of the status information of the second circuits 120-1 to 120-N may be prepared simultaneously. In this manner, the data input port IN[0] may be disconnected with the data output port OUT[0] of the second circuit 120-1.

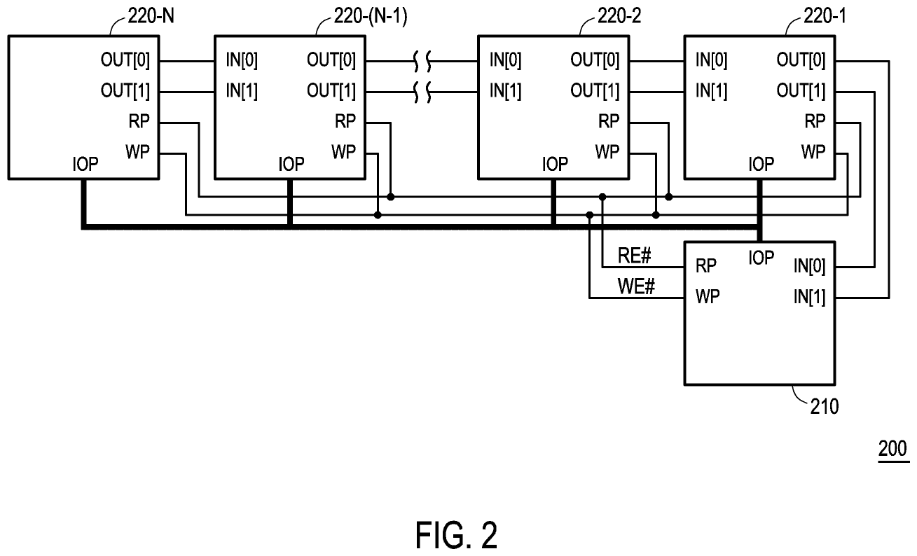

Please refer to FIG. 2, FIG. 2 is a schematic diagram of a multi-circuit control system according to another embodiment of the present disclosure. The multi-circuit control system 200 includes a first circuit 210 and a plurality of second circuits 220-1 to 220-N. The second circuits 220-1 to 220-N are coupled in series with each other, and the second circuits 220-1 to 220-N are also coupled with the first circuit 210.

Different from the embodiment in FIG. 1, each of the second circuits 220-1 to 220-N in this embodiment has a plurality of data input ports IN[0] and IN[1] and a plurality of data output ports OUT[0] and OUT[1]. The first circuit 210 also has a plurality of data input ports IN[0] and IN[1]. The data output ports OUT[0] and OUT[1] of the second circuit 220-1 of the first stage are respectively coupled to the data input ports IN[0] and IN[1] of the first circuit 210. The data input ports IN[0] and IN[1] of the second circuits 220-1 to 220-(N-1) from the first stage to the N-1-th stage are respectively coupled to the data output ports OUT[0] and OUT[1] of the second circuits 220-2 to 220-N of the subsequent stage (second stage to N-th stage).

On the other hand, in this embodiment, each of the second circuits 220-1 to 220-N may have a plurality of data shifters. One of the data shifters may be coupled between the data input port IN[0] and the data output port OUT[0], and the other data shifter may be coupled between the data input port IN[1] and the data output port OUT[1]. The data shifting operations of the second circuits 220-1 to 220-N in this embodiment are similar to the embodiment in FIG. 1, and the details will not be repeated here.

In this embodiment, the multi-circuit control system 200 may speed up the reading operation of the status information of each of the second circuits 220-1 to 220-N by arranging a plurality of data shifters in each of the second circuits 220-1 to 220-N.

It is worth mentioning that in an embodiment of the present disclosure, the number of data input ports, data output ports and corresponding data shifters in each of the second circuits 220-1 to 220-N may also be two or more. The two data input ports IN[0] and IN[1] and the two data output ports OUT[0] and OUT[1] shown in FIG. 2 are only illustrative examples, and are not intended to limit the implementation scope of the present disclosure.

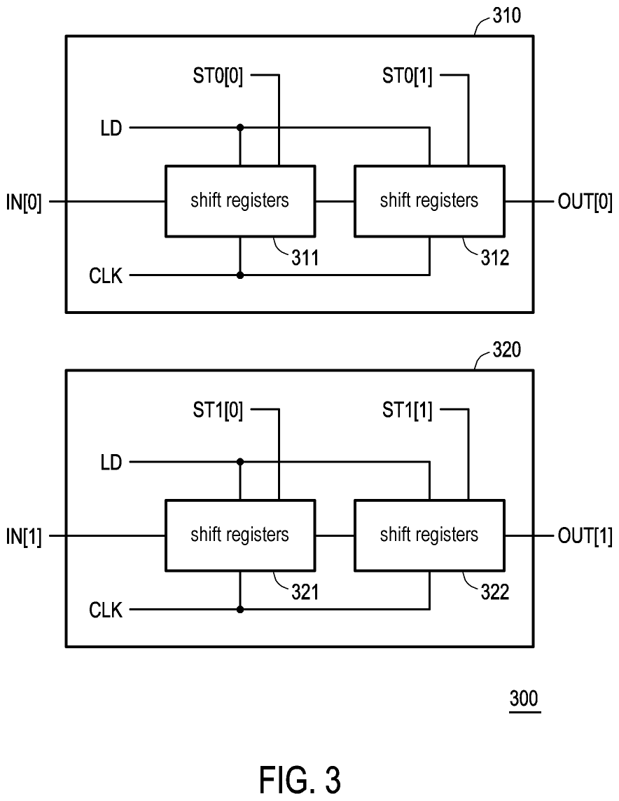

Please refer to FIG. 3. FIG. 3 is a schematic diagram illustrating the implementation of each of the second circuits in the multi-circuit control system of the embodiment of the present disclosure. The second circuit 300 includes data shifters 310 and 320. The data shifter 310 is coupled between the data input port IN[0] and the data output port OUT[0], and the data shifter 320 is coupled between the data input port IN[1] and the data output port OUT[1]. The data shifters 310 and 320 are respectively composed of two shift register groups. The shift register group in the data shifter 310 includes a plurality of shift registers 311 and 312. The shift register group in the data shifter 320 includes a plurality of shift registers 321 and 322. It should be noted that in the illustration of FIG. 3, the single shift register group including two shift registers is just an example for illustration. In an embodiment of the present disclosure, a single shift register group may include two or more registers, and there is no specific limitation. In addition, the number of data shifters in the second circuit 300 may also be two or more, and the illustration in FIG. 3 is not used to limit the number of data shifters.

In this embodiment, the shift registers 311 and 312 are sequentially coupled between the data input port IN[0] and the data output port OUT[0]. The shift registers 311 and 312 jointly receive the load signal LD, the clock signal CLK and the first part of status information ST0[0] and ST0[1]. When the status information ST0[0] and ST0[1] of the second circuit 300 is to be read, the load signal LD may be enabled to make the status information ST0[0] and ST0[1] respectively be loaded into the shift registers 311 and 312. Then, the load signal LD may be disabled, and the shift registers 311 and 312 may sequentially shift the status information ST0[0] and ST0[1] to the data output port OUT[0] according to the clock cycle of the clock signal CLK.

In addition, the shift registers 321 and 322 are sequentially coupled between the data input port IN[1] and the data output port OUT[1]. The shift registers 321 and 322 jointly receive the load signal LD, the clock signal CLK and the second part of status information ST1[0] and ST1[1]. When the load signal LD is enabled, a plurality of bits of the status information ST1[0] and ST1[1] may be loaded into the shift registers 321 and 322 respectively. Then, after the load signal LD is disabled, the shift registers 321 and 322 may sequentially shift the status information ST1[0] and ST1[1] to the data output port OUT[1] according to the clock cycle of the clock signal CLK. Moreover, the status information ST0[0] and ST0[1] and ST1[0] and ST1[1] are respectively transmitted to the second circuit of the previous stage or the first circuit through the data output port OUT[0] and OUT[1].

In addition, with the clock cycle of the clock signal CLK, the shift registers 321 and 322 may respectively receive status information sent from the second circuit of the subsequent stage through the data input ports IN[0] and IN[1], and then transmit the received status information to the second circuit of the previous stage or the first circuit through the data output port OUT[0] and OUT[1].

It is worth mentioning that in this embodiment, the clock signal CLK may be generated according to the read clock signal RE #provided by the first circuit. The load signal LD may be disabled or enabled according to the write signal WE #provided by the first circuit. Relevant implementation details will be described in detail in subsequent embodiments.

The above-mentioned shift registers 311, 312, 321 and 322 may be implemented by employing shift register circuits well known to those skilled in the art without any particular limitation.

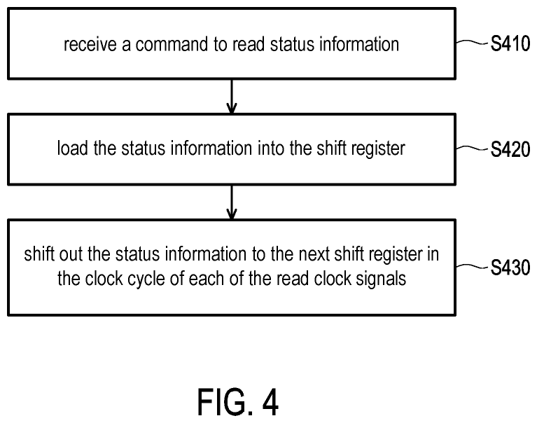

Please refer to FIG. 4. FIG. 4 is a flowchart of a method for reading status information of a multi-circuit control system according to an embodiment of the present disclosure. The multi-circuit control system includes a first circuit as a master circuit, and a plurality of second circuits as slave circuits. In step S410, a plurality of second circuits that are slave circuits receive a command to read status information sent by the first circuit of the master circuit. Next, in step S420, the status information of the second circuit may be loaded into the shift register. In step S430, the second circuit may shift out the status information to the next shift register in the clock cycle of each of the read clock signals.

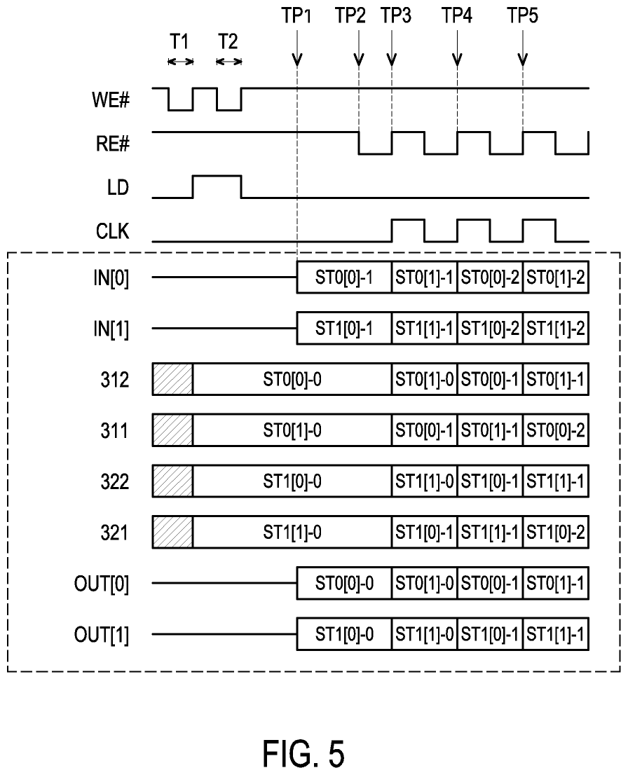

Please refer to FIG. 3 and FIG. 5 simultaneously. FIG. 5 shows an action waveform diagram of the multi-circuit control system according to an embodiment of the present disclosure. In FIG. 5, during the time interval T1, the first circuit as the master circuit sends a read command of status information to the second circuit 300 by pulling down the write signal WE #. Corresponding to the pull-down action of the write signal WE #, the second circuit 300 may enable the load signal LD by pulling the load signal LD high after the time interval T1, and make the status information ST0[0]-0, status information ST0[1]-0, status information ST1[0]-0 and status information ST1[1]-0 of the second circuit 300 be loaded into the shift registers 312, 311, 322 and 321 respectively.

In the time interval T2, the first circuit may send a dummy clock cycle by pulling down the write signal WE #again, and the second circuit 300 may disable the load signal LD by pulling down the load signal LD according to the dummy command. It is worth noting that the dummy clock cycle above is not necessarily required. The second circuit 300 may also automatically pull down the load signal LD after the load signal LD is maintained in the enabled state for a preset time.

At the time point TP1, the data input ports IN[0] and IN[1] of the second circuit 300 may respectively receive the status information ST0[0]-1 and ST1[0]-1 of the second circuit of the subsequent stage. The data output ports OUT[0] and OUT[1] of the second circuit 300 may send status information ST0[0]-0 and ST1[0]-0 respectively.

Then, after the time point TP2, the first circuit may start to provide the read clock signal RE #that is continuously transitioning. Corresponding to the transition action of the read clock signal RE #, the second circuit 300 may correspondingly generate the clock signal CLK. In the embodiment, the second circuit 300 may detect the falling edge of the read clock signal RE #, and start the transition action of the clock signal CLK according to the falling edge of the read clock signal RE #. After the time point TP1, the clock signal CLK may be in the same phase as the read clock signal RE #. Certainly, in other embodiments of the present disclosure, the clock signal CLK may also have a phase difference with the read clock signal RE #, and the transition action of the clock signal CLK may also be activated through other mechanisms based on the read clock signal RE #. For example, the second circuit 300 may count the clock cycle of the read clock signal RE #for a certain number according to the rising edge of the read clock signal RE #, or the like. Relevant details may be determined by the circuit designer without limitation.

After the time point TP2, along with the clock cycle of the clock signal CLK, the shift registers 311, 312, 321, 322 in the second circuit 300 may execute the shifting operation of the status information according to the rising edge of the clock signal CLK. Therefore, at the time point TP3, the status information ST0[0]-1 and ST1[0]-1 of the second circuit of the subsequent stage previously on the data input ports IN[0] and IN[1] are respectively shifted into the shift registers 311 and 321, and the status information ST0[1]-0 and ST1[1]-0 previously in the shift registers 311 and 321 are respectively shifted into the shift registers 312 and 322. The shift registers 312 and 322 output the stored status information ST0[1]-0 and ST1[1]-0 to the data output ports OUT[0] and OUT[1]. At this time, the data input ports IN[0] and IN[1] receive the status information ST0[1]-1 and ST1[1]-1 of the second circuit of the subsequent stage.

At time point TP4, the status information ST0[1]-1 and ST1[1]-1 of the second circuit of the subsequent stage previously on the data input ports IN[0] and IN[1] are respectively shifted into to the shift registers 311 and 321, the status information ST0[0]-1 and ST1[0]-1 previously in the shift registers 311 and 321 are respectively shifted into the shift registers 312 and 322. The shift registers 312 and 322 output the stored status information ST0[0]-1 and ST1[0]-1 to the data output ports OUT[0] and OUT[1]. At this time, the data input ports IN[0] and IN[1] receive the status information ST0[0]-2 and ST1[0]-2 of the second circuit of the two latter stages.

At the time point TP5, the status information ST0[0]-2 and ST1[0]-2 of the second circuit of the two latter stages previously on the data input ports IN[0] and IN[1] are respectively shifted into the shift registers 311 and 321, and the status information ST0[1]-1 and ST1[1]-1 previously in the shift registers 311 and 321 are respectively shifted into the shift registers 312 and 322. The shift registers 312 and 322 output the stored status information ST0[1]-1 and ST1[1]-1 to the data output ports OUT[0] and OUT[1]. At this moment, the data input ports IN[0] and IN[1] receive the status information ST0[1]-2 and ST1[1]-2 of the second circuit of the two latter stages.

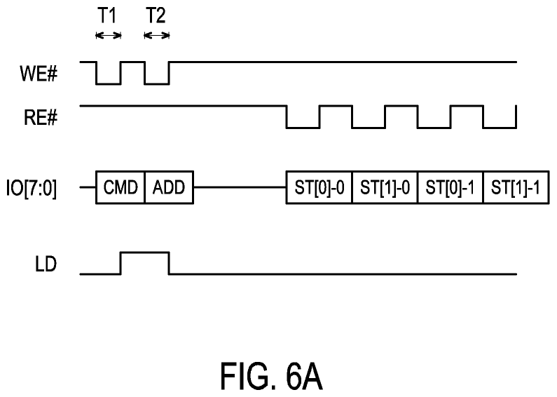

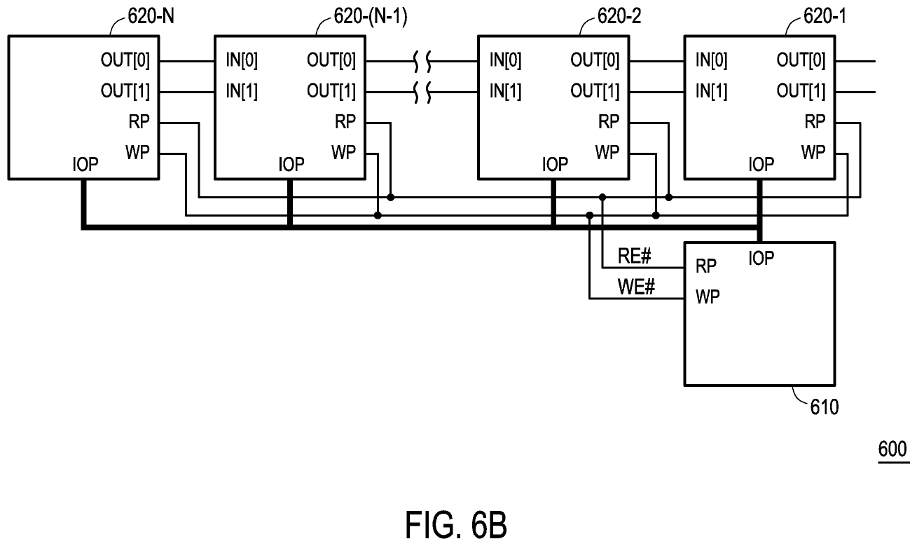

Please refer to FIG. 2 and FIG. 6A simultaneously. FIG. 6A shows an action waveform diagram of another embodiment of the multi-circuit control system of an embodiment of the present disclosure. In FIG. 6A, during the time interval T1, the first circuit 210 as the master circuit pulls down the write signal WE #, and transmits the input and output signal IO [7:0] of the command signal CMD to the second circuits 220-1 to 220-N through the parallel input and output port IOP. Next, during the time interval T2, the first circuit 210 pulls down the write signal WE #again, and transmits the input and output signal IO [7:0] which is the address signal ADD to the second circuit 220-1 to 220-N through the parallel input and output port IOP. In this embodiment, the command signal CMD is configured to convey that the first circuit 210 will perform a reading operation for status information for one of the second circuits 220-1 to 220-N. The address signal ADD is used to indicate the address information of the selected second circuit (one of the second circuits 220-1 to 220-N) to be read.

Next, the first circuit 210 may provide the read clock signal RE #, and make the selected second circuit (for example, the second circuit 220-1) sequentially transmit the input and output signals IO [7:0] as the status information ST [0]-0 and ST [1]-0 to the first circuit 210 through the parallel input and output port IOP along with the clock cycle of the read clock signal RE #. After the status information ST [0]-0 and ST [1]-0 of the second circuit 220-1 is output, the status information ST [0]-1 and ST [1]-1 of the second circuit 220-2 of the subsequent stage may be sent to the first circuit 210 through the input and output signal IO [7:0] along with the clock cycle of the read clock signal RE #.

In this embodiment, the first circuit 210 may perform a status reading operation on one of the needed second circuits 220-1 to 220-N through the parallel input and output port IOP, thereby obtaining status information of each of the second circuits 220-1 to 220-N quickly.

Please refer to FIG. 6B, FIG. 6B is a schematic diagram of a multi-circuit control system according to another embodiment of the present disclosure. The multi-circuit control system 600 includes a first circuit 610 and a plurality of second circuits 620-1 to 620-N. The second circuits 620-1 to 620-N are coupled in series with each other, and the second circuits 620-1 to 620-N are also coupled with the first circuit 610 through parallel input and output ports IOP. It should be noted here, in present embodiment, the data output ports OUT[0] and OUT[1] of the first stage second circuit 620-1 are isolated from the first chip 610. That is, the first chip 610 of this embodiment may read status information of each of the second circuits 620-1 to 620-N through the parallel input and output ports IOP in a parallel transmission scheme as the wave diagram shown as FIG. 6A.

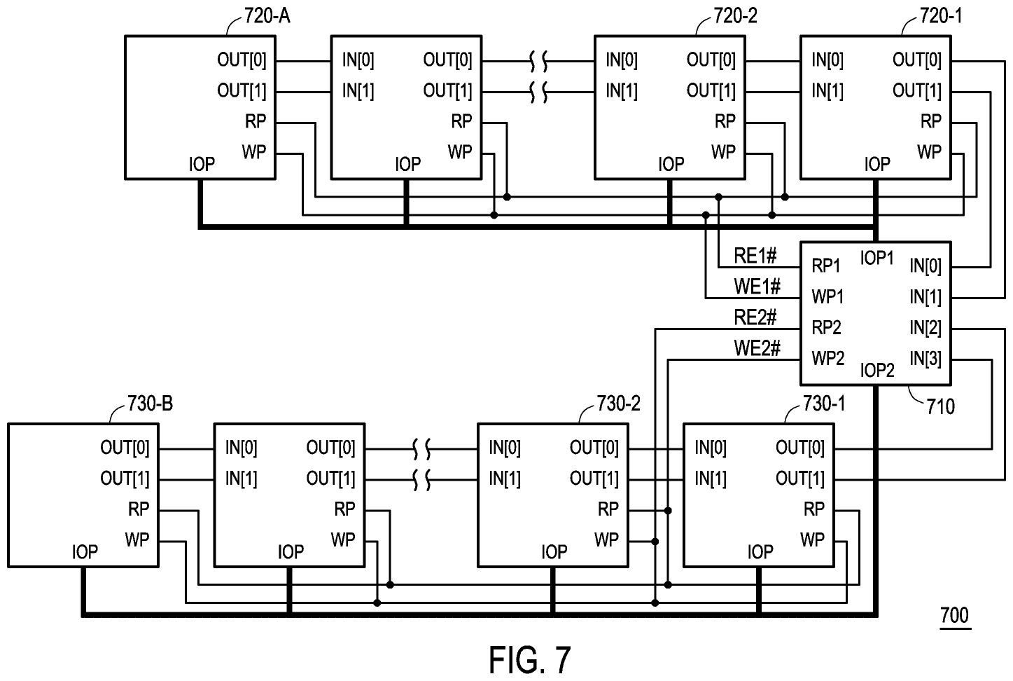

Please refer to FIG. 7, FIG. 7 is a schematic diagram of a multi-circuit control system according to another embodiment of the present disclosure. The multi-circuit control system 700 includes a first circuit 710 and a plurality of second circuits 720-1 to 720-A and 730-1 to 730-B. The second circuits 720-1 to 720-A are coupled in series with each other, and the data output ports OUT[0] and OUT[1] of the second circuit 720-1 of the first stage are respectively coupled to the data input ports IN[0] and IN[1] of the first circuit 710. In addition, the parallel input and output port IOP of each of the second circuits 720-1 to 720-A are commonly coupled to the parallel input and output port IOP1 of the first circuit 710.

In addition, the second circuits 730-1 to 730-B are coupled in series, and the data output ports OUT[0] and OUT[1] of the second circuit 730-1 of the first stage are respectively coupled to the data input ports IN[2] and IN[3] of the first circuit 710. Moreover, the parallel input and output port IOP of each of the second circuits 730-1 to 730-B are commonly coupled to the parallel input and output port IOP2 of the first circuit 710.

In this embodiment, the first circuit 710 may transmit the read clock signal RE1 #and the write signal WE1 #respectively to the second circuit 720-1 to 720-A through the read signal transmission port RP1 and the write signal transmission port WP1 to control the read action of status information. The first circuit 710 may also transmit the read clock signal RE2 #and the write signal WE2 #respectively to the second circuits 730-1 to 730-B through the read signal transmission port RP2 and the write signal transmission port WP2 to control the read action for status information. Moreover, the first circuit 710 may read the status information of any one of the second circuits 720-1 to 720-A through the parallel input and output port IOP1, and the first circuit 710 may also read the status information of any one of the second circuits 730-1 to 730-B through the parallel input and output port IOP2.

The details of the reading operation of the status information have been described in detail in the foregoing embodiments, and will not be repeated here.

It is worth mentioning that the number of second circuits 720-1 to 720-A in the series formed by the second circuits 720-1 to 720-A may be the same as or different from the number of the second circuits 730-1 to 730-B in the series formed by the second circuits 730-1 to 730-B. Moreover, in other embodiments of the present disclosure, the multi-circuit system 700 may also have another or more series formed by other second circuits. Specifically, in the multi-circuit system 700, the number of series formed by the second circuit may be one or more, and there is no specific limitation.

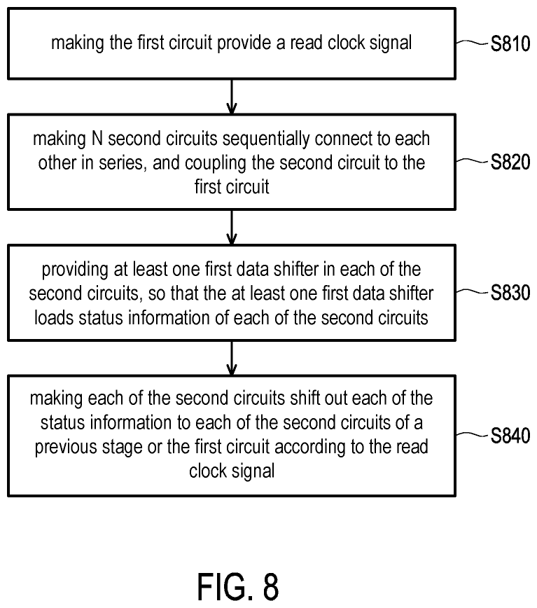

Please refer to FIG. 8, FIG. 8 is a flowchart of a method for reading status information of a multi-circuit control system according to an embodiment of the present disclosure. In step S810, the first circuit is made to provide a read clock signal. In step S820, N second circuits are sequentially coupled in series, and the second circuits are coupled to the first circuit, wherein Nis an integer greater than 1. In step S830, at least one first data shifter is provided in each of the second circuits, so that at least one first data shifter is loaded with status information of each of the second circuits. In step S840, each of the second circuits is made to shift out each status information to each of the second circuits of the previous stage or the first circuit according to the read clock signal.

The implementation details of the above steps have been described in detail in the aforementioned multiple embodiments, and will not be repeated here.

To sum up, in the multi-circuit control system of the present disclosure, by coupling the first circuit to a plurality of second circuits coupled in series, and making the first circuit provide a read clock signal, so that the status information of the plurality of the second circuits is sequentially read out along with the clock cycle of the read clock signal. The first circuit does not need to send a read command to each of the second circuits one by one to read the status information of each of the second circuits, thereby effectively saving the time required for work.

What is claimed is:

1. A multi-circuit control system, comprising:
a first circuit, providing a read clock signal; and
N second circuits, sequentially coupled in series, wherein the plurality of second circuits are coupled to the first circuit, N is an integer greater than 1,
wherein each of the plurality of second circuits has at least one first data shifter, the at least one first data shifter is configured to load status information of each of the plurality of second circuits, and shift out each of the status information to each of the plurality of second circuits of a previous stage or the first circuit according to the read clock signal, or the first chip obtains the status information of each of the second circuits through a parallel transmission scheme.

2. The multi-circuit control system according to claim 1, wherein each of the plurality of second circuits has at least one data output port and at least one data input port, and the at least one data output port and the at least one data input port are coupled to the at least one first data shifter.

3. The multi-circuit control system according to claim 2, wherein the at least one data output port of each of the plurality of second circuits of an N-th stage to a second stage is coupled to the at least one data input port of each of the plurality of second circuits of a previous stage, and the at least one data output port of the second circuit of a first stage is coupled to or isolated from the first circuit.

4. The multi-circuit control system according to claim 2, wherein each of the at least one first data shifter is a shift register group, and the shift register group is coupled between each of the at least one data input port of each of the plurality of corresponding second circuits and each of the at least one data output port.

5. The multi-circuit control system according to claim 4, wherein the shift register group comprises:
a plurality of shift registers, wherein the plurality of shift registers are coupled in series with each other,
wherein the plurality of shift registers jointly receive a load signal and the read clock signal, and respectively receive the corresponding status information.

6. The multi-circuit control system according to claim 5, wherein the plurality of shift registers respectively store bits of the status information into the plurality of shift registers according to the load signal, and perform a data shifting operation according to the read clock signal.

7. The multi-circuit control system according to claim 1, wherein the plurality of second circuits are respectively a plurality of memory circuits, and the first circuit is a memory control circuit.

8. The multi-circuit control system according to claim 1, wherein the first circuit further comprises a first parallel input and output interface, and the plurality of second circuits respectively comprise a plurality of second parallel input and output interfaces, and the first parallel input and output interface is coupled to the plurality of second parallel input and output interfaces.

9. The multi-circuit control system according to claim 8, wherein the first circuit reads the status information of one of the plurality of second circuits through the first parallel input and output interface.

10. The multi-circuit control system according to claim 1, further comprising:
N third circuits, which are sequentially coupled in series, wherein the plurality of third circuits are coupled to the first circuit,
wherein each of the plurality of third circuits has at least one second data shifter, and the at least one second data shifter is configured to load status information of each of the plurality of third circuits, and shift out each of the status information to each of the plurality of third circuits or the first circuits of a previous stage according to the read clock signal.

11. The multi-circuit control system according to claim 1, wherein the first circuit is disposed on a first chip, and the plurality of second circuits are respectively disposed on a plurality of second chips.

12. A method for reading status information, comprising:
making a first circuit provide a read clock signal;
making N second circuits sequentially coupled to each other in series, and coupling the plurality of second circuits to the first circuit, wherein N is an integer greater than 1;
providing at least one first data shifter in each of the plurality of second circuits, so that the at least one first data shifter loads status information of each of the plurality of second circuits; and
making each of the plurality of second circuits shift out each of the status information to each of the plurality of second circuits of a previous stage or the first circuit according to the read clock signal, or making the first chip obtain the status information of each of the second circuits through a parallel transmission scheme.

13. The method for reading status information according to claim 12, further comprising:
disposing a shift register group in each of the at least one first data shifter, wherein the shift register group is coupled between each of at least one data input port of each of the plurality of corresponding second circuits and each of at least one data output port.

14. The method for reading status information according to claim 13, wherein the shift register group has a plurality of shift registers coupled in series, and the method further comprises:
making the plurality of shift registers respectively store bits of the status information into the plurality of shift registers according to a load signal; and
making the plurality of shift registers perform a data shifting operation according to the read clock signal.

15. The method for reading status information according to claim 12, further comprising:
making a plurality of third circuits sequentially coupled to each other in series, and coupling the plurality of third circuits to the first circuit;
providing at least one second data shifter in each of the plurality of third circuits, so that the at least one second data shifter loads status information of each of the plurality of third circuits; and
making each of the plurality of third circuits shift out each of the status information to each of the plurality of third circuits of a previous stage or the first circuit according to the read clock signal.

16. The method for reading status information according to claim 12, further comprising:
disposing a first parallel input and output interface in the first circuit, wherein a plurality of second parallel input and output interfaces are respectively comprised in the plurality of second circuits;
coupling the first parallel input and output interface and the plurality of second parallel input and output interfaces; and
making the first circuit read the state information of one of the plurality of second circuits through the first parallel input and output interface.

17. The method for reading status information according to claim 12, further comprising:
disposing the first circuit on a first chip, so that the plurality of second circuits are respectively disposed on a plurality of second chips,
wherein the first circuit is a memory control circuit, and the plurality of second circuits are a plurality of memory circuits.
